(19) United States
(12) Patent Application Publication
(10) Pub. No.: US 2006/0181300 A1
(43) Pub. Date: Aug. 17, 2006

(54) Method for testing a circuit unit and test apparatus

(76) Inventors: Bjorn Flach, Munchen (DE); Andreas Logisch, Munchen (DE); Mehdi Rostami, Covilha (PT); Martin Schnell, Worblingen (DE)

Correspondence Address: JENKINS, WILSON, TAYLOR & HUNT, P. A., 3100 TOWER BLVD, SUITE 1200, DURHAM, NC, 27707, US

(21) Appl. No.: 11/346,518

(22) Filed: Feb. 2, 2006

(30) Foreign Application Priority Data
Feb. 16, 2005 (DE) 102005007103.1

(51) Int. Cl. G01R 31/26

(52) U.S. Cl. 324/765

(57) ABSTRACT

A test apparatus comprises a receptacle unit for holding a circuit unit to be tested and for making contact with contact-making units of the circuit unit, a test system for generating input data to be applied to the circuit unit and for analysing output data generated by the circuit unit in response to the input data, a tester channel being comprised of a plurality of lines to electrically connect the test system to connection pins which are fitted in the receptacle unit and are intended to connect the circuit unit and to communicate the input data and the output data between the test system and the circuit unit, and a signal output unit for outputting verification signals when testing the circuit unit. The signal output unit is arranged in the receptacle unit between the circuit unit and the connection pins for connecting the circuit unit.

### BACKGROUND OF THE INVENTION

1. Field of the Invention

The present invention generally relates to test systems for testing circuit units to be tested and relates, in particular, to automatic test devices (ATE, Automatic Test Equipment) which are used to ensure product quality in the semiconductor industry, in particular.

2. Description of the Prior Art

In the semiconductor industry, an automatic test unit (ATE, Automatic Test Equipment) is normally used to ensure product quality of the semiconductor apparatuses which have been produced and of the circuit units to be tested (DUT, Device Under Test). Although the quality, for example the operating behaviour, is continually being improved as regards the processing speed of the automatic test unit, it is often necessary to use an external verification device, for example an oscilloscope, to analyse and verify the waveform and the time response of different signals which are sent to the circuit unit to be tested or are sent by the latter to the tester unit. In order to analyse such signals using an oscilloscope as a verification unit, it is necessary to connect the oscilloscope or the probe head of the oscilloscope to the circuit unit to be tested (DUT) as closely as possible and with as little interference as possible. In an inexpedient manner, the circuit unit to be tested and the connection pins of the latter cannot be accessed or can be accessed only with difficulty after said circuit unit has been inserted into a test receptacle.

It is often not possible at all to reach contact-making units (connection pins) of the circuit unit to be tested if the latter is mechanically clamped to a receptacle device of the test system. In the case of mechanical clamping, it is not possible to access such connection balls or connection pins with the probe head of the oscilloscope.

The prior art has proposed numerous test apparatuses and methods in order to solve this problem. The problem of probing different contact-making units of a circuit unit to be tested is therefore dealt with in various ways because the circuit unit to be tested often has to be tested by verifying, by means of an external (additional) verification device, for example an oscilloscope, the signals which enter the circuit unit to be tested and are output from the circuit unit to be tested during testing using a test system.

FIG. 1 shows a conventional test apparatus in which a circuit unit to be tested DUT has been inserted into a receptacle S using a test device TE. The contact-making units K of the circuit unit to be tested DUT are connected to a test system (not shown) via a tester channel L1 (which comprises a plurality of lines) and connection pins A. In order to connect these contact-making units K of the circuit unit to be tested DUT to an external verification device, for example an oscilloscope O, via a verification channel L2, bushings D or holes must be disadvantageously provided in the test device. Providing such holes is extremely disadvantageous since changes to the test device are undesirable. It is also inexpedient that there is a very unstable connection since the verification wire L2 (verification channel) which has been inserted could short-circuit different contact-making units K of the circuit unit to be tested DUT (oriented perpendicular to the plane of the figure). The electrical connection between the tester channel L2 (which comprises a plurality of lines) and a contact-making unit K is also unreliable since the verification channel L2 can easily disengage from the contact-making unit K.

Another disadvantage of the conventional test apparatus shown in FIG. 1 resides in the fact that high-speed signals cannot be measured since they require a very good earth connection which additionally has to be laid close to the signal path. It can clearly be seen that, in the conventional test apparatus shown in FIG. 1, the connection of the verification channel must be laid at such a distance from an earth connection that high-speed signals cannot be reliably transmitted.

It is also inexpedient that the test apparatus shown in FIG. 1 cannot be used to make contact with so-called ball grid arrays (BGA) since such contact-making balls (contact-making units) are arranged underneath the circuit unit to be tested DUT.

In order to also be able to use conventional methods to test circuit units DUT which are to be tested and have ball grid arrays, the prior art has proposed the test apparatus which is shown in FIG. 2 and in which so-called test points TP are arranged in the receptacle S into which the circuit unit to be tested DUT is introduced. External verification devices, for example an oscilloscope O, may be connected to these test points which are connected to connection pins A of the receptacle unit via the verification channel L2. However, line branches, that is to say branching of the verification channels L2 from a tester channel L1 which comprises a plurality of lines and connects the connection pins A of the receptacle S to a test system TS, disadvantageously result in this case.

In a disadvantageous manner, a signal cannot be measured close to a contact-making unit K of the circuit unit to be tested DUT. In this way, it is uncertain whether the signal which reaches the circuit unit to be tested or the signal which is output from the circuit unit to be tested DUT is the same as that which is measured via the verification channel L2. It is also inexpedient that crosstalk, reflections and other interference can occur in the event of the verification channel L2 branching off from the tester channel L1 which comprises a plurality of lines.

### SUMMARY OF THE INVENTION

It is an object of the present invention to provide a test apparatus for testing a circuit unit to be tested, in the case of which apparatus it is possible for verification signals to be tapped off in a reliable and interference-free manner during testing of the circuit unit to be tested.

The object is achieved in accordance with the invention by means of a test apparatus for testing a circuit unit to be tested, comprising:
a) a receptacle unit for holding the circuit unit to be tested and for making contact with contact-making units of the circuit unit to be tested;
b) a test system for generating desired data which are supplied to the circuit unit to be tested and for analysing actual data which are output from the circuit unit to be tested on the basis of the desired data which are supplied to the latter; and
c) a tester channel which comprises a plurality of lines and is intended to electrically connect the test system to connection pins which are fitted in the receptacle unit and are intended to connect the circuit unit to be tested and to communicate desired data and actual data between the test system and the circuit unit to be tested, the test apparatus also having a signal output unit for outputting verification signals when testing the circuit unit to be tested, and the signal output unit also being arranged in the receptacle unit between the circuit unit to be tested and the connection pins for connecting the circuit unit to be tested.

The object is also achieved in accordance with the invention by means of a test method for testing a circuit unit to be tested, comprising the steps of:
a) using a receptacle unit to hold the circuit unit to be tested and to make contact with contact-making units of the circuit unit to be tested;
b) using a tester channel which comprises a plurality of lines to electrically connect the test system to connection pins which are fitted in the receptacle unit and are intended to connect the circuit unit to be tested to a test system and to communicate desired data and actual data between the test system and the circuit unit to be tested;
c) using the test system to generate the desired data which are supplied to the circuit unit to be tested; and
d) using the test system to analyse the actual data which are output from the circuit unit to be tested on the basis of the desired data which are supplied to the latter, a signal output unit, which is arranged in the receptacle unit between the circuit unit to be tested and the connection pins for connecting the circuit unit to be tested, being used to output verification signals when testing the circuit unit to be tested.

A fundamental concept of the invention involves providing, in the receptacle unit, a signal output unit for outputting verification signals when testing the circuit unit to be tested, said signal output unit being arranged between the circuit unit to be tested and connection pins for connecting the circuit unit to be tested.

The advantage of the inventive test apparatus resides in the fact that it is possible to tap off verification signals in a safe and reliable manner without interfering reflections. In this way, certain signals which are supplied to the circuit unit to be tested or are output from the circuit unit to be tested can be verified in an efficient and reliable manner and with high contact stability.

It is also an advantage that only slight changes have to be made in comparison with the conventional receptacle arrangement.

The signal output unit which is arranged in the receptacle unit between the circuit unit to be tested and the connection pins for connecting the circuit unit to be tested may be in the form of a signal decoupling layer. The signal decoupling layer preferably has the same area as the circuit unit to be tested.

The verification signals which are output, using the signal output unit, when testing the circuit unit to be tested can be verified in a verification device. The verification apparatus may be expediently formed by an oscilloscope. The verification signals which are output, using the signal output unit, when testing the circuit unit to be tested are verified in a verification device. The verification device may automatically be connected to the signal output unit using a plug connection. In this manner, the present invention makes it possible for verification signals to be output in a reliable and efficient manner by means of a verification channel when testing circuit units to be tested.

Exemplary embodiments of the invention are illustrated in the drawings and are explained in more detail in the following description.

### DESCRIPTION OF THE DRAWINGS

FIG. 1, as discussed above, is a conventional test apparatus for making contact with circuit units which are to be tested and have lateral contact-making units.

FIG. 2 as discussed above, is another test apparatus according to the prior art for making contact with circuit units which are to be tested and have contact-making balls on the underside of the corresponding circuit unit to be tested.

FIG. 3 is a basic design of a receptacle unit to which the present invention is applied.

FIG. 4 is a first exemplary embodiment of an inventive receptacle unit.

FIG. 5 is a detail view of the signal output unit with contact-making units of the circuit unit of FIG. 4.

FIG. 6 is a modified arrangement of FIG. 4, wherein a plug connection for automatically connecting a verification device to the signal output unit is additionally be provided.

### DESCRIPTION OF THE PREFERRED EMBODIMENTS

In the figures, identical reference symbols denote identical or functionally identical components or steps.

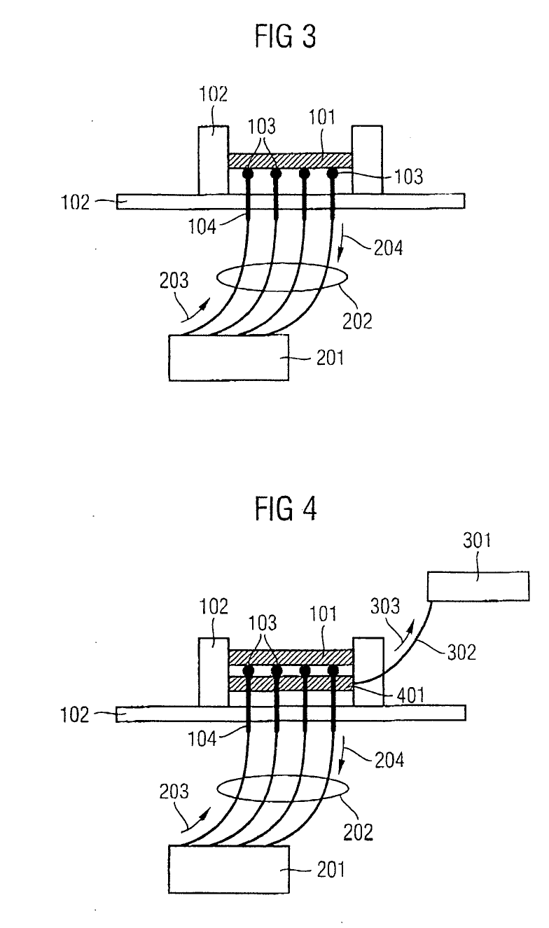

FIG. 3 shows a receptacle unit 102 to which the present invention is applied. The receptacle unit 102 has connection pins 104 which make contact, in pressing-on fashion, with contact-making units 103 of a circuit unit 101 to be tested. The connection pins 104 are connected to corresponding lines (tester lines) of a tester channel 202 which comprises a plurality of lines and is used to electrically connect the circuit unit 101 to be tested to a test system 201.

After the test system 201 has been electrically connected to the connection pins 104 which are fitted in the receptacle unit 102 and are intended to connect the circuit unit 101 to be tested, desired data 203 and actual data 204 may be interchanged by the test system 201 and the circuit unit 101 to be tested via the tester channel 202 which comprises a plurality of lines.

In this case, the desired data 203 are generated using the test system 201 and are output to the circuit unit 101 to be tested. The actual data 204 which are output from the circuit unit 101 to be tested on the basis of the desired data 203 supplied to the latter are also analysed in the test system 201.

FIG. 4 then shows an exemplary embodiment of the invention for using a signal output unit 401 which is arranged in the receptacle unit 102 between the circuit unit 101 to be tested and the connection pins 104 for connecting the circuit unit 101 to be tested to output verification signals 303 when testing the circuit unit 101 to be tested. The verification signals 303 are supplied to a verification device which is in the form of a cathode-ray oscilloscope or a digital oscilloscope, for example. The signal output unit 401 may preferably be in the form of a signal decoupling layer.

Such a signal decoupling layer will be explained in more detail below with reference to FIG. 5. The signal output unit 401 which may also be in the form of a printed circuit board makes it possible for all of the connection pins 104 to be simultaneously connected to contact-making units 103 of the circuit unit 101 to be tested. The signal output unit 401 also electrically connects all of the connection pins 104 to a verification channel 302 which can be used to supply the verification signals 303 to the verification device 301.

FIG. 5 shows the signal output unit 401 with a part of the circuit unit 101 to be tested and two contact-making units 103a, 103b in greater detail. A connection pin 104 which makes contact with the signal output unit 401 at the place of an electrical connection to the contact-making unit 103a which is in the form of a data pin is also shown. The further contact-making unit 103b which is arranged beside the data pin is in the form of an earth connection (earth pin) which makes contact directly with an earth layer or an earth connection 402. The signal output unit 401 is now designed in such a manner that provision is made of a tapping resistor 304 which is connected to the verification channel 302 and can output a verification signal 303 to the external verification device 301 (not shown in FIG. 5) without interfering reflections.

In order to avoid signal reflections on lines which are not connected, such lines should be terminated with a 50 Ω resistor. The screen of the signal cable which forms the verification channel 302 to the verification device 301 should be connected to the earth connections 402 of the signal output unit 401 and/or to the corresponding earth contact-making units 103b of the circuit unit to be tested.

The inventive test apparatus with the provision of a signal output unit 401 has the advantage, in particular, that only slight changes in the operating behaviour are expected as a result of the conventional receptacle being modified. Measurements using all standard receptacle units are advantageously possible without making relatively great changes to the test apparatus. Another advantage resides in the fact that, in comparison with probe measurements, numerous signals can be simultaneously output because decoupling is effected directly in the path between the signal output unit 401 and the verification channel 302. In principle, all signals, that is to say desired data 203 which are supplied to the circuit unit 101 to be tested and actual data 204 which are output from the circuit unit 101 to be tested, can be simultaneously tested in the verification device 301.

It is also possible for voltage supply lines which are connected to the signal output unit 401 to be monitored in order to detect, for example, voltage drops under normal operating conditions. The measurements can be carried out at high or low temperatures, it being possible to heat or cool the apparatus in a temperature chamber.

The electrical connections between the tester channel 202 (which comprises a plurality of lines) and the circuit unit 101 to be tested, on the one hand, and between the verification channel 302 and the circuit unit 101 to be tested, on the other hand, are reliably retained since thermal expansion exerts a smaller influence on the contact-making process than test apparatuses according to the prior art.

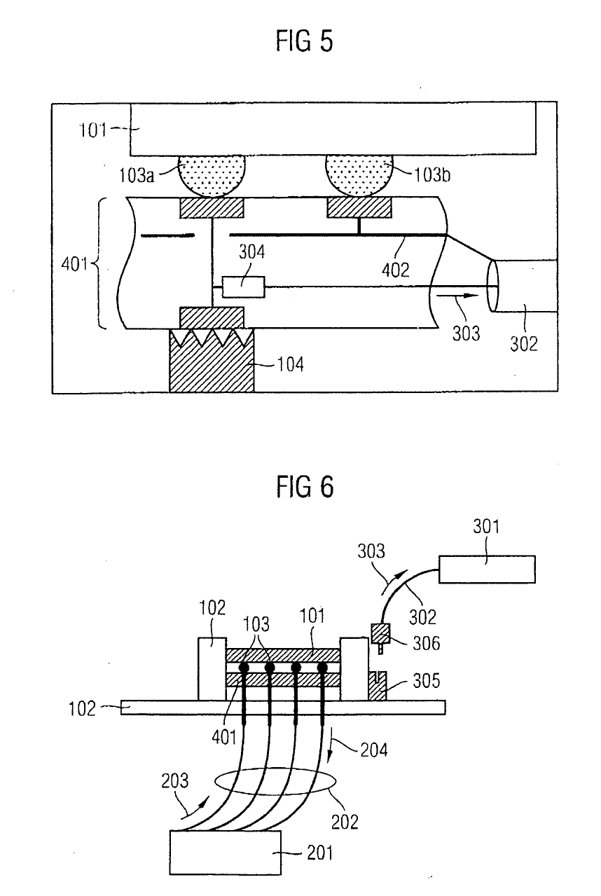

FIG. 6 finally shows the arrangement which is shown in FIG. 4 and has been extended by a plug connection 305, 306 for automatically connecting the verification device 301 to the signal output unit 401. For this purpose, different circuit units 101 to be tested may be successively connected to a verification device 301 by dint of a robot system or a programmable RF mixer.

It shall be pointed out that the signal decoupling unit 401 may be permanently introduced into the receptacle unit 102 in order to connect the tester channel 202 which comprises a plurality of lines to the circuit unit 101 to be tested. It is also possible for the signal output unit 401 to be fitted in the receptacle unit 102 such that said signal output unit can be removed and for the latter to be introduced into the receptacle unit 102 only when verification signals 303 are to be discharged to a verification device 301 via the verification channel 302.

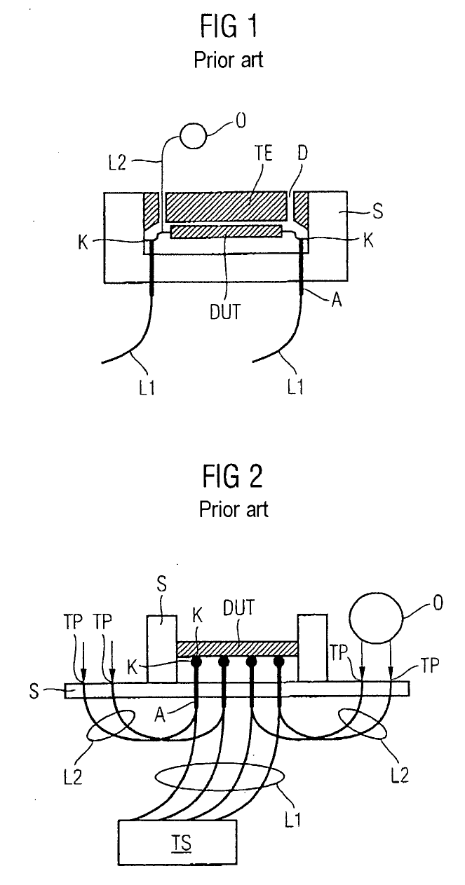

Reference is made to the introduction to the description as regards the conventional test apparatus which is illustrated in FIGS. 1 and 2 and is intended to test circuit units to be tested.

Although the present invention was described above with reference to preferred exemplary embodiments, it is not restricted thereto but rather can be multifariously modified.

Moreover, the invention is not restricted to the application possibilities mentioned.

We claim as our invention:

1. A test apparatus for testing a circuit unit, comprising:
a receptacle unit for holding a circuit unit to be tested and for making contact with contact-making units of said circuit unit;
a test system for generating input data to be applied to said circuit unit and for analysing output data generated by said circuit unit in response to said input data;
a tester channel being comprised of a plurality of lines to electrically connect said test system to connection pins which are fitted in said receptacle unit and are intended to connect said circuit unit and to communicate said input data and said output data between said test system and said circuit unit; and
a signal output unit for outputting verification signals when testing said circuit unit; said signal output unit being arranged in said receptacle unit between said circuit unit and said connection pins for connecting said circuit unit.

2. The apparatus of claim 1, wherein said signal output unit is in the form of a signal decoupling layer.

3. The apparatus of claim 1, wherein said verification signals are verified in a verification device.

4. The apparatus of claim 3, wherein said verification device is an oscilloscope.

5. A test method for testing a circuit unit, comprising the steps of:
using a receptacle unit to hold a circuit unit to be tested and to make contact with contact-making units of said circuit unit;
using a tester channel being comprised of a plurality of lines to electrically connect a test system to connection pins which are fitted in said receptacle unit and are intended to connect said circuit unit to said test system and to communicate input data and output data between said test system and said circuit unit;
using said test system to generate said input data which are supplied to said circuit unit; and
using said test system to analyse said output data which are output from said circuit unit in response to said input data; and
using a signal output unit being arranged in said receptacle unit between said circuit unit and said connection pins for connecting said circuit unit to output verification signals when testing said circuit unit.

6. The method of claim 5, comprising verifying said verification signals in a verification device.

7. The method of claim 6, comprising automatically connecting said verification device to said signal output unit using a plug connection.
